(19) United States
(12) Patent Application Publication
(10) Pub. No.: US 2025/0140719 A1
(43) Pub. Date: May 1, 2025

(54) SEMICONDUCTOR APPARATUS

(71) Applicant: Mitsubishi Electric Corporation, Tokyo (JP)

(72) Inventors: Seiya NAKANO, Tokyo (JP); Hiroya HAMADA, Tokyo (JP)

(73) Assignee: Mitsubishi Electric Corporation, Tokyo (JP)

(21) Appl. No.: 18/667,915

(22) Filed: May 17, 2024

(30) Foreign Application Priority Data
Oct. 27, 2023 (JP) 2023-184349

(51) Int. Cl. H01L 23/00; H01L 23/36; H01L 29/739

(52) U.S. Cl. CPC H01L 24/05; H01L 23/36; H01L 2224/02175; H10D 12/481

(57) ABSTRACT

According to the present disclosure, a semiconductor apparatus comprises a semiconductor substrate, on a front surface of which a semiconductor device is formed, a surface electrode formed on the front surface and connected to the semiconductor device, a metal film formed on the surface electrode, a suppression film formed on the surface electrode and configured to suppress the spread of solder applied on the metal film, and a thermally conductive film formed further on an outer periphery side than the metal film and the suppression film on the surface electrode, thicker than the metal film, and having higher thermal conductivity than the suppression film.

### BACKGROUND OF THE INVENTION

### Field

The present disclosure relates to a semiconductor apparatus.

### Background

There has been disclosed a technique of covering, with a protective film, a terminal end of a surface electrode formed on a conduction region of a semiconductor apparatus and bonding the surface electrode and an external electrode with solder (see, for example, Japanese Patent No. 4640345).

However, when the thermal conductivity of the protective film is low, an overlapping region of the protective film and the conduction region generates heat according to an overload such as a short-circuit resistance test.

There has been a problem in that the short-circuit resistance in the overlapping region is deteriorated by the heat generation.

### SUMMARY

In view of the above-described problems, an object of the present disclosure is to provide a semiconductor apparatus that can improve short-circuit resistance.

The features and advantages of the present disclosure may be summarized as follows.

A semiconductor apparatus according to the present disclosure includes: a semiconductor substrate, on a front surface of which a semiconductor device is formed, a surface electrode formed on the front surface and connected to the semiconductor device, a metal film formed on the surface electrode, a suppression film formed on the surface electrode and configured to suppress the spread of solder applied on the metal film, and a thermally conductive film formed further on an outer periphery side than the metal film and the suppression film on the surface electrode, thicker than the metal film, and having higher thermal conductivity than the suppression film.

Other and further objects, features and advantages of the disclosure will appear more fully from the following description.

### BRIEF DESCRIPTION OF DRAWINGS

FIG. 1 is a top view illustrating a configuration of a semiconductor apparatus according to a first embodiment of the present disclosure.

FIG. 2 is a sectional view illustrating the configuration of the semiconductor apparatus according to the first embodiment of the present disclosure.

FIG. 3 is a sectional view illustrating a configuration of a semiconductor apparatus according to a second embodiment of the present disclosure.

FIG. 4 is a sectional view illustrating a configuration of a semiconductor apparatus according to a third embodiment of the present disclosure.

FIG. 5 is a sectional view illustrating a configuration of a semiconductor apparatus according to a fourth embodiment of the present disclosure.

FIG. 6 is a sectional view illustrating a configuration of a semiconductor apparatus according to a fifth embodiment of the present disclosure.

FIG. 7 is a sectional view illustrating a configuration of a semiconductor apparatus according to a sixth embodiment of the present disclosure.

FIG. 8 is a top view illustrating a configuration of a semiconductor apparatus according to a seventh embodiment of the present disclosure.

FIG. 9 is a sectional view illustrating a configuration of a semiconductor apparatus according to an eighth embodiment of the present disclosure.

### DESCRIPTION OF EMBODIMENTS

### First Embodiment

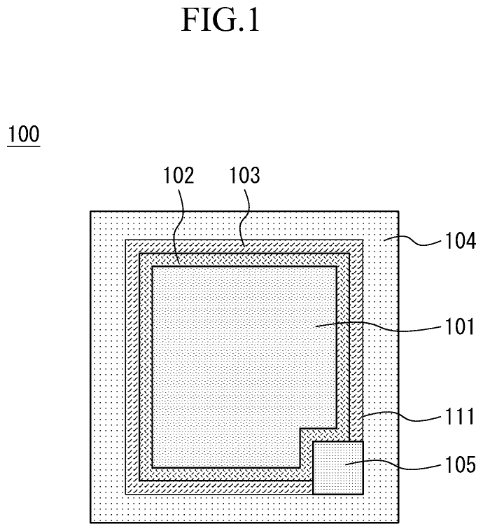

FIG. 1 is a top view illustrating a configuration of a semiconductor apparatus according to a first embodiment of the present disclosure. A first region 101 is provided in the center of a semiconductor apparatus 100. The first region 101 is a region where soldering is performed.

A second region 102 surrounds the first region 101. The second region 102 is a region for suppressing the spread of solder.

A third region 103 surrounds the second region 102. The third region 103 is a region for improving short-circuit resistance.

A fourth region 104 surrounds the third region 103. A gate pad is formed in a fifth region 105 at a corner of the semiconductor apparatus 100. The first region 101, the second region 102, the third region 103, and the fifth region 105 are located on the inner side of a conduction region 111. The fourth region 104 covers the outer periphery of the conduction region 111 and the outer side of the conduction region 111.

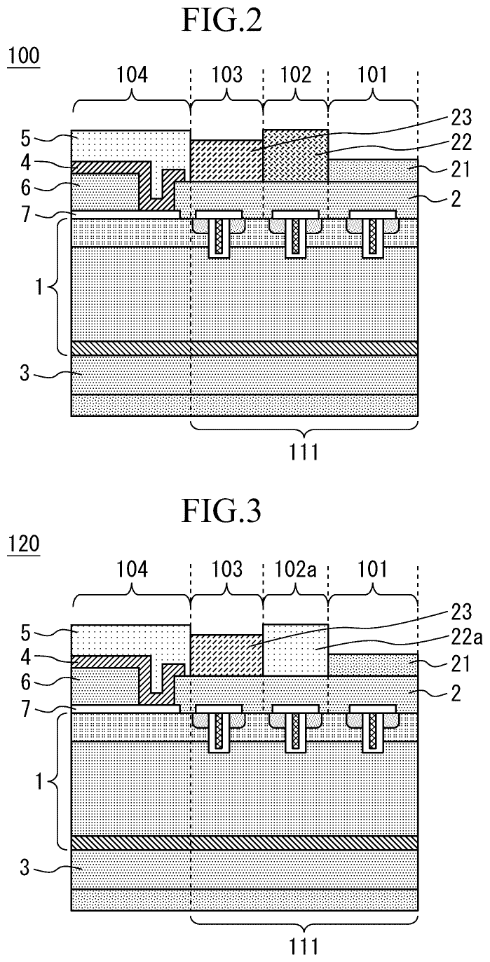

FIG. 2 is a sectional view illustrating the configuration of the semiconductor apparatus according to the first embodiment of the present disclosure. FIG. 2 is an enlarged diagram of a part of the cross section of the semiconductor apparatus 100 illustrated in FIG. 1.

The semiconductor apparatus 100 includes a semiconductor substrate 1. The semiconductor substrate 1 is formed of, for example, Si. A back electrode 3 is connected to the rear surface of the semiconductor substrate 1.

A semiconductor device is formed on the front surface of the semiconductor substrate 1. The semiconductor device is, for example, an IGBT. Note that the conduction region 111 illustrated in FIG. 1 is a region where the semiconductor device is formed on the front surface of the semiconductor substrate 1.

Note that the semiconductor substrate 1 may be formed of a material having a larger bandgap compared with Si. That is, the semiconductor device may be formed by a wide band gap semiconductor. The wide band gap semiconductor is, for example, silicon carbide, a gallium nitride-based material, or diamond.

A surface electrode 2 is formed on the front surface of the semiconductor substrate 1 above the semiconductor device. The surface electrode 2 is formed of, for example, AlSi. The surface electrode 2 is connected to the semiconductor device.

A metal film 21 is formed on the center of the surface electrode 2. The metal film 21 has a solderable configuration and is, for example, a metal film containing Ni or Au. For example, the metal film 21 may be formed by a plating method or may be formed by a sputtering method. The surface electrode 2 and an external electrode can be directly bonded by the metal film 21 using solder. Note that the first region 101 illustrated in FIG. 1 is a region where the metal film 21 is formed and solder can be applied.

A suppression film 22 is formed on the surface electrode 2 to surround the outer periphery of the metal film 21 in plan view. The suppression film 22 is formed of a material having poorer solder wettability compared with the metal film 21 and is formed of, for example, a nonmetal material. The suppression film 22 suppresses the spread of solder applied on the metal film 21. Note that the second region 102 illustrated in FIG. 1 is a region where the suppression film 22 is formed.

A thermally conductive film 23 is formed further on the outer periphery side than the metal film 21 and the suppression film 22 on the surface electrode 2. The thermally conductive film 23 is thicker than the metal film 21 and is formed of a material having higher thermal conductivity than the suppression film 22. The thermally conductive film 23 is, for example, a metal film containing Ni or Au. Note that the third region 103 illustrated in FIG. 1 is a region where the thermally conductive film 23 is formed.

Here, a heat dissipation path from the third region 103 is conceived. When the thermally conductive film 23 is absent, a main heat dissipation path of heat generated in the conduction region 111 is a first path passing through the surface electrode 2, the metal film 21, the solder, and the external electrode. However, the thermally conductive film 23 is present in the semiconductor apparatus 100 of the present disclosure. Therefore, the heat dissipation path of the heat generated in the conduction region 111 is, in addition to the first path, a second path passing through the surface electrode 2, the thermally conductive film 23, and a module sealing material which is not illustrated. That is, since the heat dissipation paths are increased by the thermally conductive film 23, it is possible to suppress heat generation involved in an overload and improve short-circuit resistance. Note that, as a test involving the heat generation involved in the overload, a test for applying a short pulse, like a short-circuit break test, can be exemplified.

An insulating film 7 is formed in an outer peripheral region of the conduction region 111 on the front surface of the semiconductor substrate 1. A gate wire 6 is disposed on the insulating film 7. A nitride film 4 is formed on the gate wire 6. The nitride film 4 is formed of, for example, silicon nitride. The nitride film 4 is a film having adhesion to a semiconductor and insulation for electric discharge suppression on the fourth region 104.

The terminal end of the surface electrode 2 and the nitride film 4 are covered with a protective film 5. That is, the protective film 5 covers the terminal end of the surface electrode 2 further on the outer periphery side than the thermally conductive film 23. The protective film 5 is formed of, for example, polyimide. The protective film 5 is a film having insulation for electric discharge suppression, strength for protecting a semiconductor apparatus from stress after module mounting and a temperature cycle, heat resistance, and low thermal shrinkage. The protective film 5 is often thicker than the gate wire 6 in order to prevent, by ensuring flatness, stress from concentrating in a region having a film thickness difference.

Note that the fourth region 104 illustrated in FIG. 1 is a region where the protective film 5 is formed. The nitride film 4 and the protective film 5 are formed to protect the fourth region 104 by enabling voltage resistance retention, humidity resistance improvement, and stress relaxation after module mounting. The nitride film 4 and the protective film 5 have transparency. This makes it possible to determine, with an exterior inspection from above, a foreign matter or a pattern formation failure on the fourth region 104.

Note that, in the above description, the gate wire 6 is present in the fourth region 104, which is the nonconduction region. However, a terminal end region, a wiring section, or the like may be disposed in the fourth region 104.

### Second Embodiment

FIG. 3 is a sectional view illustrating a configuration of a semiconductor apparatus according to a second embodiment of the present disclosure. A semiconductor apparatus 120 according to the second embodiment is different from the semiconductor apparatus 100 in that a suppression film 22a formed in a second region 102a is formed of the same material as the protective film 5.

Since the suppression film 22a is formed of the same material as the protective film 5, the suppression film 22a can be formed simultaneously with the protective film 5. That is, steps can be reduced from the steps in the first embodiment.

Note that, when the thermal conductivity of the protective film 5 is low, since the thermal conductivity of the suppression film 22a will also become low, the short-circuit resistance in the second region 102a can deteriorate. However, since the second region 102a is located between the first region 101 and the third region 103 that have high heat dissipation, the heat dissipation path is considered to disperse. This makes it possible to suppress the deterioration of the short-circuit resistance.

In FIG. 3, the second region 102a has the same width as the third region 103. However, the area of the second region 102a may be set smaller than the area of the third region 103 to further suppress the deterioration of the short-circuit resistance. Theoretically, the width of the second region 102a is considered to be able to be set to the width of the minimum dimension in which the protective film 5 can be disposed.

### Third Embodiment

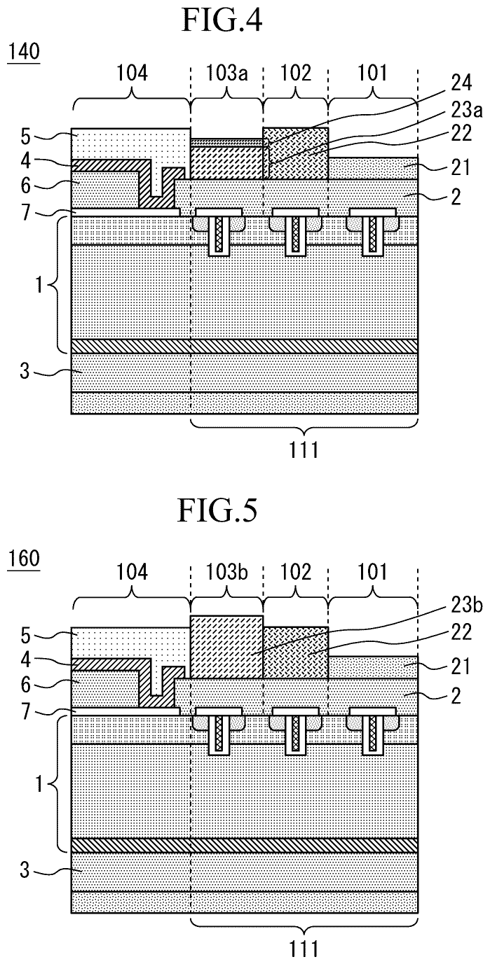

FIG. 4 is a sectional view illustrating a configuration of a semiconductor apparatus according to a third embodiment of the present disclosure. A semiconductor apparatus 140 according to the third embodiment is different from the semiconductor apparatus 100 in that a thermally conductive film formed in a third region 103a has a two-layer structure.

The semiconductor apparatus 140 includes a thermally conductive film 23a. The thermally conductive film 23a is a film having the same characteristics as the thermally conductive film 23. A coating film 24 is formed on the thermally conductive film 23a. The coating film 24 is formed of a material different from the thermally conductive film 23a. The coating film 24 may be configured not to hinder heat dissipation from, for example, the thermally conductive film 23a. The coating film 24 may be formed of, for example, a material that is difficult to increase in film thickness, or a material having low thermal conductivity.

In a manufacturing process for the semiconductor apparatus 100, the material of an outermost surface film of the third region 103 is sometimes limited. When the limited material is the material that is difficult to increase in film thickness, or the material having low thermal conductivity, it becomes difficult to form the thermally conductive film 23.

However, in the semiconductor apparatus 140, the thermally conductive film formed in the third region 103a has the two-layer structure of the thermally conductive film 23a and the coating film 24. Therefore, the limitation of the material in the manufacturing process is satisfied by the coating film 24 and, at the same time, the problem of the present disclosure can be solved by the thermally conductive film 23a.

The coating film 24 is formed to fill the film thickness difference between the protective film 5 and the thermally conductive film 23a. This makes it possible to ensure the flatness of the entire film. Therefore, it is possible to prevent stress from concentrating in a region having a film thickness difference.

Alternatively, the thermally conductive film 23a is formed of the same material as the surface electrode 2 and the coating film 24 is formed of the same material as the metal film 21, whereby the thermally conductive film formed in the third region 103a may be two-layered. In this case, it is possible to reduce types of materials necessary for manufacturing the semiconductor apparatus 140 and reduce steps.

### Fourth Embodiment

FIG. 5 is a sectional view illustrating a configuration of a semiconductor apparatus according to a fourth embodiment of the present disclosure. A semiconductor apparatus 160 according to the fourth embodiment is different from the semiconductor apparatus 100 in that the thickness of a thermally conductive film 23b formed in a third region 103b is greater than the thickness of the suppression film 22.

The semiconductor apparatus 160 includes the thermally conductive film 23b. The thermally conductive film 23b is thicker than the metal film 21 and the suppression film 22 and is formed of a material having thermal conductivity higher than the thermal conductivity of the suppression film 22. Since the thermally conductive film 23b is thicker than the thermally conductive film 23, heat capacity increases. This makes it possible to further enhance the effect of improving short-circuit resistance.

### Fifth Embodiment

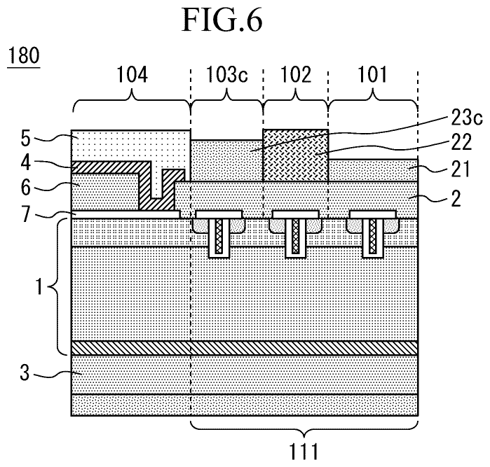

FIG. 6 is a sectional view illustrating a configuration of a semiconductor apparatus according to a fifth embodiment of the present disclosure. A semiconductor apparatus 180 according to the fifth embodiment is different from the semiconductor apparatus 100 in that the material of a thermally conductive film 23c formed in a third region 103c is the same as the material of the other films.

The semiconductor apparatus 180 includes the thermally conductive film 23c. The thermally conductive film 23c is formed of the same material as the surface electrode 2, for example, AlSi. This makes it possible to reduce types of materials necessary for manufacturing the semiconductor apparatus 180.

Note that an example in which the thermally conductive film 23c is formed of the same material as the surface electrode 2 is described above. However, the thermally conductive film 23c may be formed of the same material as the metal film 21 or the nitride film 4. In this case, it is possible to reduce types of materials necessary for manufacturing the semiconductor apparatus 180 and reduce steps.

### Sixth Embodiment

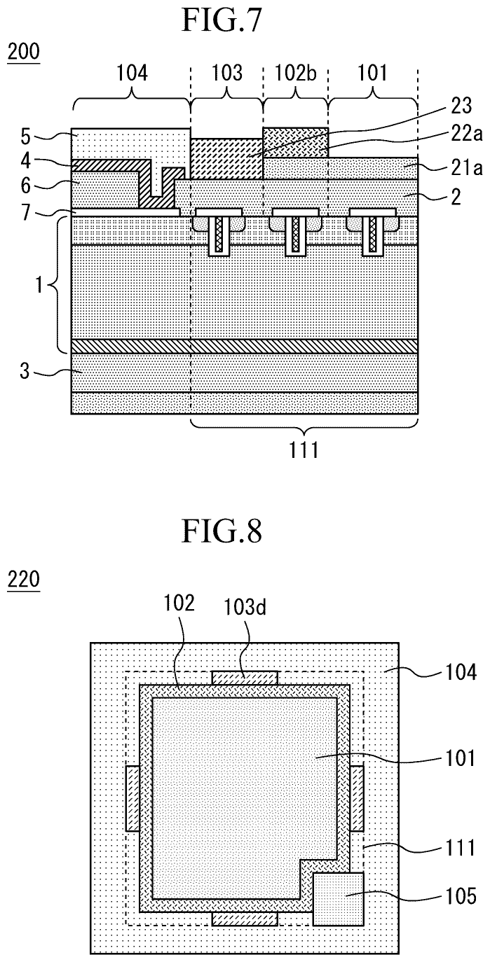

FIG. 7 is a sectional view illustrating a configuration of a semiconductor apparatus according to a sixth embodiment of the present disclosure. A semiconductor apparatus 200 according to the sixth embodiment is different from the semiconductor apparatus 100 in that the suppression film 22a is formed on an outer peripheral region of a metal film 21a.

In the semiconductor apparatus 200, the metal film 21a is formed on the surface electrode 2. The metal film 21a has a solderable configuration and is, for example, a metal film containing Ni or Au. For example, the metal film 21a may be formed by a plating method or may be formed by a sputtering method. The surface electrode 2 and an external electrode can be directly bonded by the metal film 21a using solder.

The suppression film 22a is formed on the outer peripheral region of the metal film 21a.

The suppression film 22a is formed of a material having poor solder wettability and is formed of, for example, a nonmetal material. The spread of solder applied on the metal film 21a can be suppressed by the suppression film 22a.

As described above, the suppression film 22a is formed on the outer peripheral region of the metal film 21a. That is, the metal film 21a having high thermal conductivity is disposed in a second region 102b as well. This makes it possible to further enhance the effect of improving short-circuit resistance.

### Seventh Embodiment

FIG. 8 is a top view illustrating a configuration of a semiconductor apparatus according to a seventh embodiment of the present disclosure. A semiconductor apparatus 220 according to the seventh embodiment is different from the semiconductor apparatus 100 in that third regions 103d are disposed in only parts of an inner peripheral region of the fourth region 104.

The semiconductor apparatus 220 includes the third regions 103d. The third regions 103d are regions for improving short-circuit resistance because the thermally conductive film 23 is formed on the surface layers of the third regions 103d. The third regions 103d are disposed at the center of the sides of a quadrangle forming the inner periphery of the fourth region 104, formed in a quadrangular frame shape in plan view. That is, the thermally conductive film 23 is disposed near the center of the sides of a quadrangle forming the inner periphery of the protective film 5, formed in a quadrangular frame shape in plan view.

As described above, the third regions 103d are selectively disposed in parts that easily generate heat. The parts that easily generate heat are, for example, the vicinities of the center of the conduction region 111. This makes it possible to more efficiently obtain the effect of the third regions 103d. Therefore, layout flexibility is improved.

Note that, when a resistance component of the gate wire 6 is considered, responsiveness to the ON and OFF of the gate voltage is lower in a part more distant from the fifth region 105, which is the gate pad. That is, since the timing of the gate voltage being turned off is delayed, it is possible that the part becomes a part that easily generates heat. Therefore, the third regions 103d may be disposed in parts distant from the fifth region 105.

### Eighth Embodiment

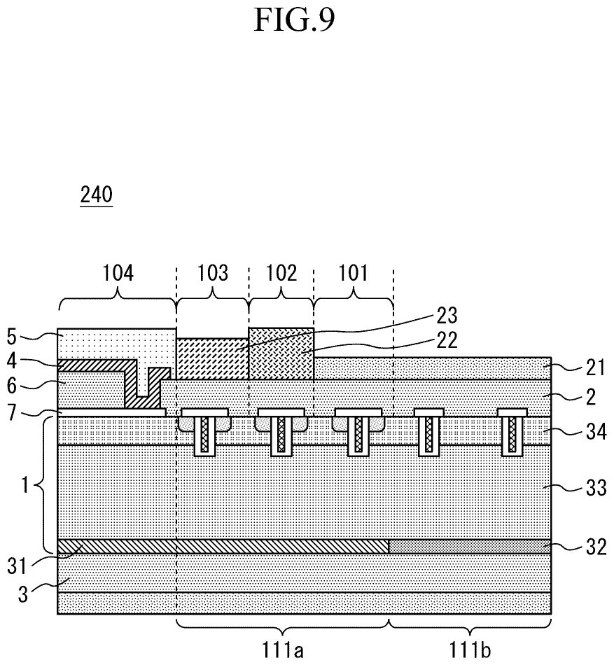

FIG. 9 is a sectional view illustrating a configuration of a semiconductor apparatus according to an eighth embodiment of the present disclosure. A semiconductor apparatus 240 according to the eighth embodiment is different from the semiconductor apparatus 100 in that a semiconductor device is an RC-IGBT.

The semiconductor apparatus 240 includes a p-type semiconductor region 31 on the rear surface side of the semiconductor substrate 1. The p-type semiconductor region 31 functions as a collector of an IGBT in a region where the IGBT is formed on the front surface of the semiconductor substrate 1. The region where the IGBT is formed is referred to as conduction region 111a.

The semiconductor apparatus 240 includes an n-type semiconductor region 32 on the rear surface side of the semiconductor substrate 1. The n-type semiconductor region 32 functions as an anode of a Diode in a region where the Diode is formed on the front surface of the semiconductor substrate 1. The region where the Diode is formed is referred to as conduction region 111b.

As described above, the conduction region 111a has a function of the IGBT and the conduction region 111b has a function of the Diode. That is, the conduction regions 111a and 111b operate as the RC-IGBT. This makes it possible to reduce the chip mounting area, and improve the reliability of the semiconductor apparatus.

Hereinafter, various aspects of the present disclosure will be collectively described as appendixes.

### Appendix 1

A semiconductor apparatus comprising:
a semiconductor substrate, on a front surface of which a semiconductor device is formed;
a surface electrode formed on the front surface and connected to the semiconductor device;
a metal film formed on the surface electrode;
a suppression film formed on the surface electrode and configured to suppress the spread of solder applied on the metal film; and
a thermally conductive film formed further on an outer periphery side than the metal film and the suppression film on the surface electrode, thicker than the metal film, and having higher thermal conductivity than the suppression film.

### Appendix 2

The semiconductor apparatus according to appendix 1, further comprising a protective film configured to cover a terminal end of the surface electrode further on the outer periphery side than the thermally conductive film, wherein
the suppression film is formed of a same material as the protective film.

### Appendix 3

The semiconductor apparatus according to appendix 1 or 2, further comprising a coating film formed on the thermally conductive film and formed of a material different from a material of the thermally conductive film

### Appendix 4

The semiconductor apparatus according to any one of appendixes 1 to 3, wherein the thermally conductive film is thicker than the suppression film.

### Appendix 5

The semiconductor apparatus according to any one of appendixes 1 to 4, wherein the thermally conductive film is formed of a same material as the surface electrode.

### Appendix 6

The semiconductor apparatus according to any one of appendixes 1 to 5, wherein the suppression film is formed on the surface electrode to surround an outer periphery of the metal film in plan view.

### Appendix 7

The semiconductor apparatus according to any one of appendixes 1 to 5, wherein the suppression film is formed on an outer peripheral region of the metal film.

### Appendix 8

The semiconductor apparatus according to appendix 2, wherein
the protective film is formed in a quadrangular frame shape in plan view, and
the thermally conductive film is disposed in the center of the sides of a quadrangle forming an inner periphery of the protective film.

### Appendix 9

The semiconductor apparatus according to any one of appendixes 1 to 8, wherein the semiconductor device is an RC-IGBT.

### Appendix 10

The semiconductor apparatus according to any one of appendixes 1 to 9, wherein the semiconductor device is formed by a wide band gap semiconductor.

### Appendix 11

The semiconductor apparatus according to appendix 10, wherein the wide band gap semiconductor is silicon carbide, a gallium nitride-based material, or diamond.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2023-184349, filed on Oct. 27, 2023 including specification, claims, drawings and summary, on which the Convention priority of the present application is based, are incorporated herein by reference in its entirety.

1. A semiconductor apparatus comprising:
a semiconductor substrate, on a front surface of which a semiconductor device is formed;
a surface electrode formed on the front surface and connected to the semiconductor device;
a metal film formed on the surface electrode;
a suppression film formed on the surface electrode and configured to suppress the spread of solder applied on the metal film; and
a thermally conductive film formed further on an outer periphery side than the metal film and the suppression film on the surface electrode, thicker than the metal film, and having higher thermal conductivity than the suppression film.

2. The semiconductor apparatus according to claim 1, further comprising a protective film configured to cover a terminal end of the surface electrode further on the outer periphery side than the thermally conductive film, wherein
the suppression film is formed of a same material as the protective film.

3. The semiconductor apparatus according to claim 1, further comprising a coating film formed on the thermally conductive film and formed of a material different from a material of the thermally conductive film.

4. The semiconductor apparatus according to claim 1, wherein the thermally conductive film is thicker than the suppression film.

5. The semiconductor apparatus according to claim 1, wherein the thermally conductive film is formed of a same material as the surface electrode.

6. The semiconductor apparatus according to claim 1, wherein the suppression film is formed on the surface electrode to surround an outer periphery of the metal film in plan view.

7. The semiconductor apparatus according to claim 1, wherein the suppression film is formed on an outer peripheral region of the metal film.

8. The semiconductor apparatus according to claim 2, wherein
the protective film is formed in a quadrangular frame shape in plan view, and
the thermally conductive film is disposed in the center of the sides of a quadrangle forming an inner periphery of the protective film.

9. The semiconductor apparatus according to claim 1, wherein the semiconductor device is an RC-IGBT.

10. The semiconductor apparatus according to claim 1, wherein the semiconductor device is formed by a wide band gap semiconductor.

11. The semiconductor apparatus according to claim 10, wherein the wide band gap semiconductor is silicon carbide, a gallium nitride-based material, or diamond.
